(19) United States
(12) Patent Application Publication
(10) Pub. No.: US 2022/0408556 A1
(43) Pub. Date: Dec. 22, 2022

(54) WIRING CIRCUIT BOARD

(71) Applicant: NITTO DENKO CORPORATION, Osaka (JP)

(72) Inventors: Rihito FUKUSHIMA, Osaka (JP); Shusaku SHIBATA, Osaka (JP); Yusaku TAMAKI, Osaka (JP)

(73) Assignee: NITTO DENKO CORPORATION, Osaka (JP)

(21) Appl. No.: 17/776,476

(22) PCT Filed: Nov. 5, 2020
(86) PCT No.: PCT/JP2020/041316

§ 371 Date: May 12, 2022

(30) Foreign Application Priority Data
Nov. 20, 2019 (JP) 2019-209294

(51) Int. Cl. H05K 1/02

(52) U.S. Cl. CPC H05K 1/0298; H05K 2201/09236

(57) ABSTRACT

A wiring circuit board includes an insulating layer, a pair of wiring layers, an insulating layer, and a wiring layer. The pair of wiring layers are disposed on the insulating layer and extend side by side apart from each other. The insulating layer is disposed on the insulating layer so as to cover the pair of wiring layers. The wiring layer is disposed on the insulating layer and extends along the pair of wiring layers, while facing to the pair of wiring layers in a thickness direction of the wiring layer. The wiring layer has a ridge portion. The ridge portion protrudes into the insulating layer toward a region between the wiring layers and extends along the region.

### TECHNICAL FIELD

The present invention relates to a wiring circuit board.

### BACKGROUND ART

Some of semiconductor components to be mounted on a wiring circuit board increase in size along with higher functionality. Some of wiring circuit boards have a limit to the size and may be required to be downsized, from the viewpoint of miniaturization of a device into which the wiring circuit board is incorporated. Accordingly, the wiring circuit boards tend to lose an area for forming a wiring.

In accordance with such a tendency, when wires are formed finely in width and gap on the same plane of a substrate, reliability and production yield of the wiring circuit board are likely to decrease. Therefore, it has been considered to make the wiring on the substrate into two layers in order to cope with a decrease in a wiring formation area. Such technique relating to two-layer structure of the wiring is, for example, described in Patent Document I below.

### CITATION LIST

### Patent Document

Patent Document 1: Japanese Unexamined Patent Publication No. 2009-252816

### SUMMARY OF THE INVENTION

### Problem to be Solved by the Invention

On the other hand, there is also a demand for lower resistance of wiring, whose density is increasing on wiring boards.

The present invention provides a wiring circuit board suitable for achieving high density, while achieving low resistance of a wiring.

### Means for Solving the Problem

The present invention [1] includes a wiring circuit board including a first insulating layer, a pair of first wiring layers disposed on the first insulating layer and extending side by side apart from each other, a second insulating layer disposed on the first insulating layer so as to cover the pair of first wiring layers, and a second wiring layer disposed on the second insulating layer and extending along the pair of first wiring layers, the second wiring layer facing to the pair of first wiring layers in a thickness direction of the first wiring layer, wherein the second wiring layer has a ridge portion protruding into the second insulating layer toward a region between the pair of first wiring layers and, extending along the region.

The wiring circuit board of the present invention, as described above, includes the pair of first wiring layers, and the second wiring layer extending along the first wiring layers while facing them. Such a wiring circuit board is suitable for achieving high density of the wiring. Along with this, the second wiring layer, as described above, has the ridge portion protruding into the second insulating layer toward the region between the first wiring layers, and extending along the region. Such a configuration is suitable for achieving an increase in the cross-sectional area of the second wiring layer by effectively utilizing a space between the first wiring layers, and therefore, is suitable for achieving a decrease in electrical resistance (low resistance). In addition, the ridge portion of the second wiring layer works to ensure adhesion of the second wiring layer to the second insulating layer by an anchoring effect to the second insulating layer, and therefore, is suitable for ensuring reliability of the second wiring layer.

The present invention [2] includes the wiring circuit board described in the above-described [1], wherein the ridge portion has an apex portion non-flat in a cross section in a width direction crossing an extending direction of the second wiring layer.

A configuration in which the ridge portion has such an apex portion serves to ensure the adhesion of the second wiring layer to the second insulating layer by the anchoring effect of the ridge portion to the second insulating layer, and therefore, is suitable for ensuring the reliability of the second wiring layer.

The present invention [3] includes the wiring circuit board described in the above-described [2], wherein the ridge portion further has a first curved side surface disposed at one side of the apex portion in the width direction and recessed inwardly in the second wiring layer, and a second curved side surface disposed at the other side of the apex portion in the width direction and recessed inwardly in the second wiring layer.

A configuration in which the ridge portion has the first and the second curved side surfaces serves to ensure the adhesion of the second wiring layer to the second insulating layer by the anchoring effect of the ridge portion to the second insulating layer, and therefore, is suitable for ensuring the reliability of the second wiring layer.

The present invention [4] includes the wiring circuit board described in any one of the above-described [1] to [3], wherein a distance between the first wiring layer and the second wiring layer in the thickness direction is 2 μm or more and 20 μm or less.

Such a configuration is suitable for achieving a thin wiring circuit board, while avoiding a short circuit between the first wiring layer and the second wiring layer.

The present invention [5] includes the wiring circuit board described in any one of the above-described [1] to [4], wherein a distance between the pair of first wiring layers is 5 μm or more and 30 μm or less.

Such a configuration is suitable for achieving high density of the wiring, while avoiding a short circuit between the first wiring layers.

### BRIEF DESCRIPTION OF THE DRAWINGS

FIG. 1 shows a schematic plan view of one embodiment of a wiring circuit board of the present invention.

FIG. 2 shows a cross-sectional view of a multilayer wiring structure portion in a width direction in one embodiment of the wiring circuit board of the present invention.

FIG. 3 shows a partial cross-sectional view of the multilayer wiring structure portion in an extending direction in one embodiment of the wiring circuit board of the present invention.

FIG. 4 shows a part of steps in a method for producing one embodiment of the wiring circuit board of the present invention as a change in a cross section corresponding to FIG. 2:

FIG. 4A illustrating a preparation step,

FIG. 4B illustrating a first insulating layer forming step, and

FIG. 4C illustrating a first conductive portion forming step.

FIG. 5 shows steps following the steps shown in FIG. 4:

FIG. 5A illustrating a second insulating layer forming step,

FIG. 5B illustrating a second conductive portion forming step, and

FIG. 5C illustrating a third insulating layer forming step.

FIG. 6 shows a part of steps in the method for producing one embodiment of the wiring circuit board of the present invention as a change in a cross section corresponding to FIG. 3:

FIG. 6A illustrating a preparation step,

FIG. 6B illustrating a first insulating layer forming step, and

FIG. 6C illustrating a first conductive portion forming step,

FIG. 7 shows steps following the steps shown in FIG. 6:

FIG. 7A illustrating a second insulating layer forming step,

FIG. 7B illustrating a second conductive portion forming step, and

FIG. 7C illustrating a third insulating layer forming step.

FIG. 8 shows a partial cross-sectional view of a multilayer wiring structure portion in an extending direction in a modified example of a wiring circuit board.

### DESCRIPTION OF EMBODIMENTS

FIGS. 1 to 3 show a wiring circuit board X which is one embodiment of the present invention. FIG. 1 shows a schematic plan view of the wiring circuit board X. FIG. 2 shows a cross-sectional view of a multilayer wiring structure portion in a width direction in the wiring circuit board X. FIG. 3 shows a partial cross-sectional view of the multilayer wiring structure portion in an extending direction in the wiring circuit board X.

As shown in FIG. 1, the wiring circuit board X has component mounting regions R1 and a wiring formation region R2 around them. The component mounting region R1 is a region where a mounting component such as a semiconductor chip is disposed. The component mounting region R1 is provided with pad portions (not shown) for electrical connection with the mounting component. A plurality of wirings (not shown) are formed in the wiring formation region R2. Examples of the plurality of wirings include power supply wirings, signal wirings, and ground wirings. At least a part of the plurality of wirings are electrically connected to terminal portions for external connection (not shown) provided in the wiring formation region R2. Further, the wiring circuit board X includes the multilayer wiring structure portion shown in FIGS. 2 and 3 in the wiring formation region R2.

The multilayer wiring structure portion is a wiring structure portion including wirings extending side by side facing each other in a thickness direction, and includes an insulating layer 11 as a first insulating layer, an insulating layer 12 as a second insulating layer, an insulating layer 13 as a third insulating layer, a pair of wiring layers 21 as a pair of first wiring layers, and a wiring layer 22 as a second wiring layer. FIGS. 2 and 3 illustratively show the multilayer wiring structure portion disposed on a substrate S.

The substrate S is an element for ensuring strength of the wiring circuit board X, and is provided in the entire or a part of region of the wiring circuit board X, when viewed from the top shown in FIG. 1.

When the wiring circuit board X is configured as a flexible wiring circuit board, the substrate S is, for example, a flexible metal support layer. Examples of a constituent material of the metal support layer include metal foils. Examples of a metal material of the metal foil include stainless steel, 42-alloy, copper, and copper alloy. An example of the stainless steel includes SUS304 based on standards of the AISI (American Iron and Steel Institute). The substrate S, as a metal support layer, has a thickness of, for example, 15 μm or more, and for example, 500 μm or less, preferably 250 μm or less.

When the wiring circuit board X is configured as a rigid wiring circuit board, the substrate S is a rigid substrate. Examples of the rigid substrate include glass epoxy substrates and metal flat plates. The substrate S, as a rigid substrate, has a thickness of, for example, 0.1 mm or more, and for example, 2 mm or less, preferably 1.6 mm or less.

The insulating layer 11 is formed on one surface in the thickness direction of the substrate S. Examples of a constituent material of the insulating layer 11 include synthetic resins such as polyimide, polyether nitrile, polyether sulfone, polyethylene terephthalate, polyethylene naphthalate, and polyvinyl chloride (examples of a constituent material of the insulating layers 12 and 13 to be described later include the same synthetic resins). The insulating layer 11 has a thickness of, for example, 1 μm or more, preferably 3 μm or more, and for example, 35 μm or less, preferably 15 μm or less.

The pair of wiring layers 21 and 21 are disposed on one surface in the thickness direction of the insulating layer 11. The pair of wiring layers 21 and 21 extend side by side spaced apart from each other. In such an embodiment, the pair of wiring layers 21 and 21 have a predetermined pattern shape on the insulating layer 11.

The wiring layer 21 has a thickness of, for example, 3 μm or more, preferably 5 μm or more, and for example, 50 μm or less, preferably 30 μm or less. The wiring layer 21 has a width (dimension in a direction perpendicular to the extending direction of the wiring layer 21) of, for example, 5 μm or more, preferably 8 μm or more, and for example, 100 μm or less, preferably 50 μm or less. A distance L1 in a separation direction between the pair of wiring layers 21 and 21 is preferably 5 μm or more, more preferably 8 μm or more, and preferably 30 μm or less, more preferably 20 μm or less.

Examples of a constituent material of the wiring layer 21 include metal materials such as copper, nickel, gold, solder, and alloys of these, and preferably, copper is used (the same applies to a constituent material of the wiring layer 22 to be described later).

The insulating layer 12 is disposed on one surface in the thickness direction of the insulating layer 11 so as to cover the pair of wiring layers 21 and 21. A thickness (maximum height from the insulating layer 11) of the insulating layer 12 is larger than that of the wiring layer 21.

As shown in FIG. 2, the wiring layer 22 is disposed on one surface in the thickness direction of the insulating layer 12, and faces the pair of wiring layers 21 and 21 in the thickness direction through the insulating layer 12. Along with this, as shown in FIG. 3, the wiring layer 22 extends along each of the pair of wiring layers 21 and 21. The wiring layer 22 is, for example, connected to an electrically conductive pad portion which is not shown provided on the insulating layer 11.

The wiring layer 22 has a width (dimension in a direction perpendicular to the extending direction of the wiring layer 22) of, for example, 8 μm or more, preferably 10 μm or more, and for example, 100 μm or less, preferably 80 μm or less as long as the wiring layer 22, as described above, faces the pair of wiring layers 21 and 21.

The wiring layer 22 has a ridge portion 22A. As shown in FIG. 2, the ridge portion 22A protrudes into the insulating layer 12 toward a region G between the pair of wiring layers 21 and 21, and extends along the region G. The ridge portion 22A has an apex portion 22a. The apex portion 22a has a non-flat and outwardly expanding curved surface in a cross section (cross section shown in FIG. 2) in the width direction crossing (perpendicular to, in the present embodiment) the extending direction of the wiring layer 22.

As shown in FIG. 2, the ridge portion 22A has a curved side surface 22b (first curved side surface) and a curved side surface 22c (second curved side surface). The curved side surface 22b is disposed at one side of the apex portion 22a in the width direction, and recessed inwardly in the wiring layer 22. The curved side surface 22c is disposed at the other side of the apex portion 22a in the width direction, and recessed inwardly in the wiring layer 22.

Further, the wiring layer 22 has a part 22F at a position between the pair of wiring layers 21 and 21 in the separation direction (specifically, a position for forming the ridge portion 22A). The part 22F is thicker than a part 22E facing the wiring layer 21. The part 22E has a thickness of preferably 3 μm or more, more preferably 5 μm or more, and preferably 50 μm or less, more preferably 30 μm or less. The part 22F has a thickness of preferably 3 μm or more, more preferably 5 μm or more, and preferably 60 μm or less, more preferably 40 μm or less as long as it is thicker than the part 22E.

A distance L2 between the wiring layer 21, and the wiring layer 22 or the part 22E thereof in the thickness direction is preferably 2 μm or more, more preferably 5 μm or more, and preferably 20 μm or less, more preferably 15 μm or less.

The insulating layer 13 is disposed on one surface in the thickness direction of the insulating layer 12 so as to cover the wiring layer 22. A thickness (height from the insulating layer 12) of the insulating layer 13 is larger than that of the wiring layer 22. The insulating layer 13 has a thickness of, for example, 4 μm or more, preferably 6 μm or more, and for example, 60 μm or less, preferably 40 μm or less as long as it is thicker than the wiring layer 22.

The wiring layer 21 and the wiring layer 22 in the multilayer wiring structure portion of the wiring circuit board X are a signal wiring, or a power supply wiring (that is, a wiring for power supply). The power supply wiring often has a strong demand for low resistance, and the wiring circuit board X is suitable for achieving high density and low resistance in such a power supply wiring.

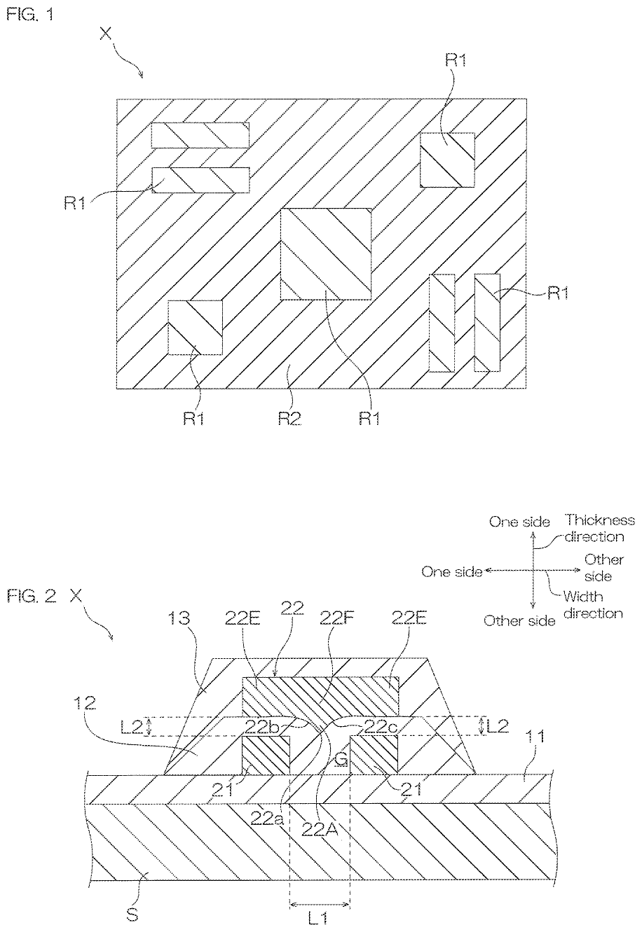

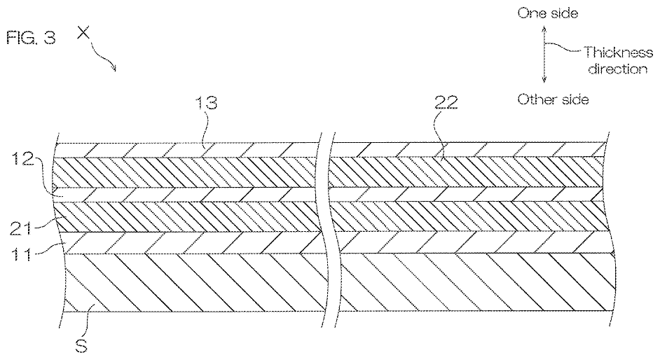

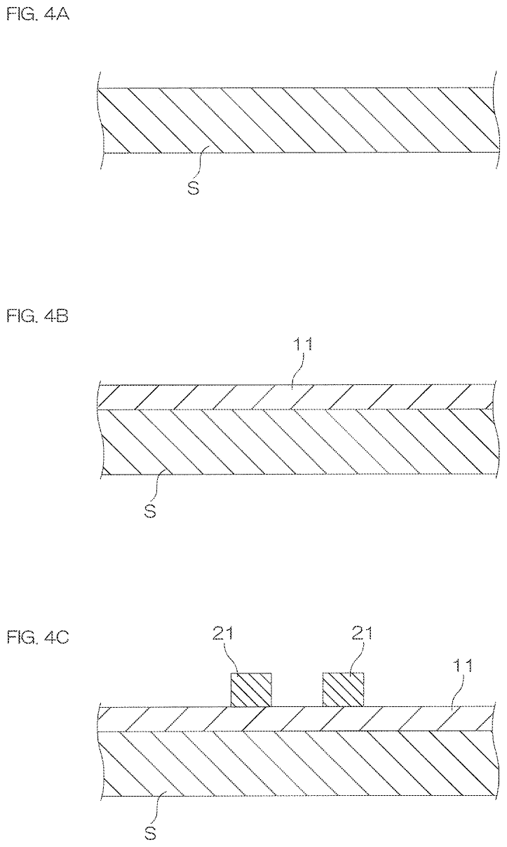

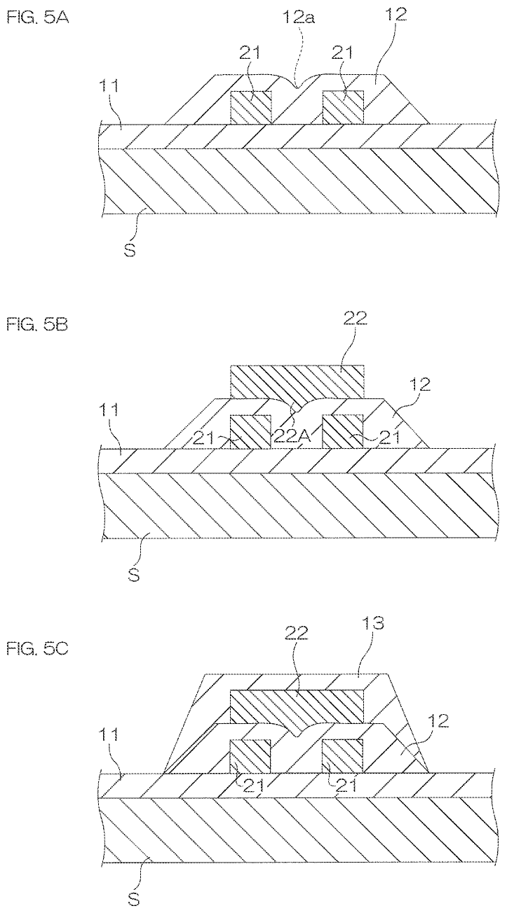

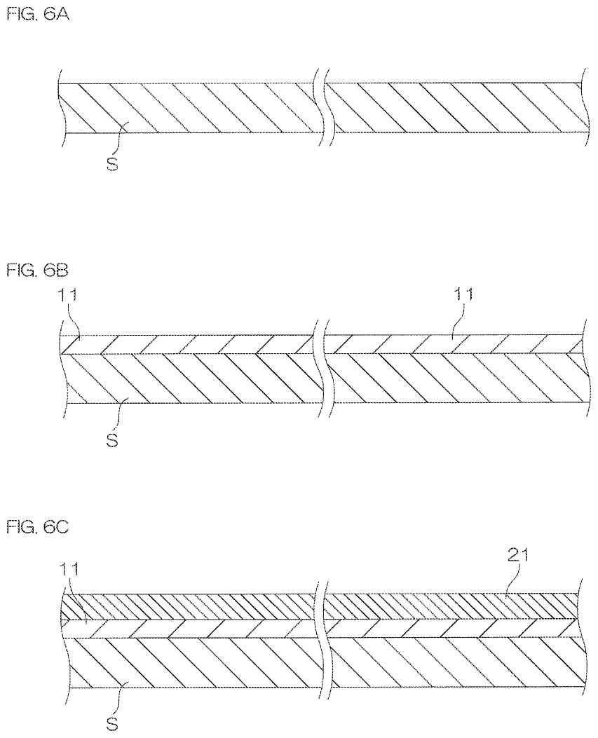

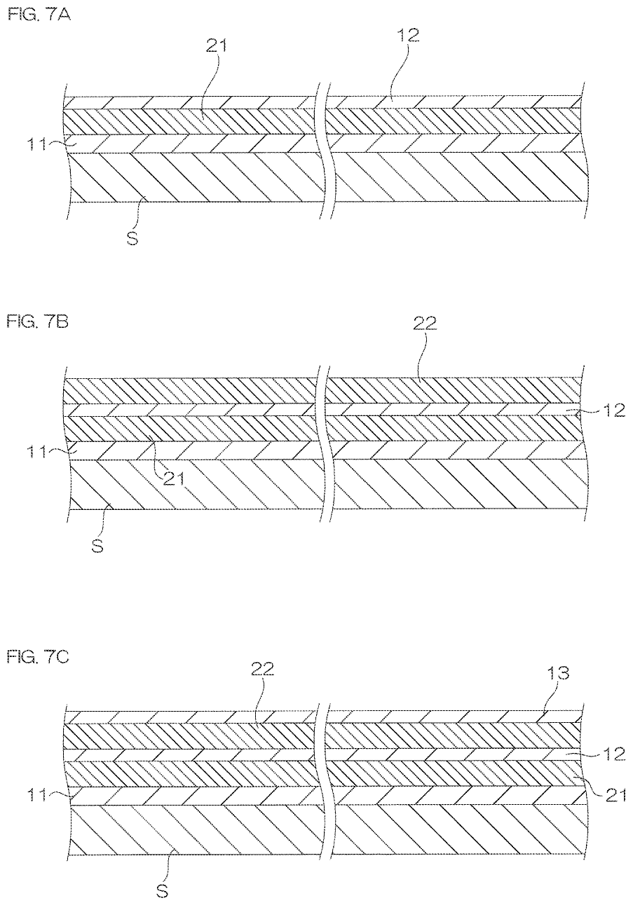

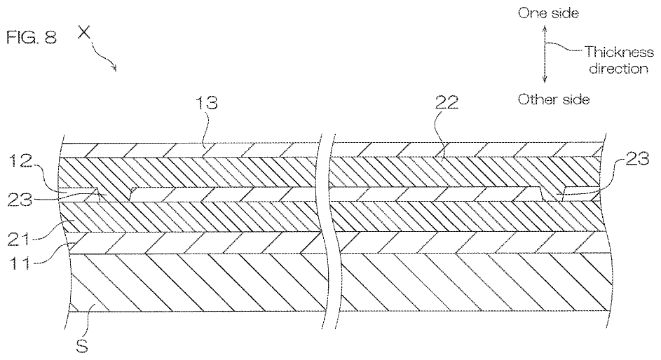

FIGS. 4 to 7 show one example of a method for producing the wiring circuit board X. FIGS. 4 and 5 show the present production method as a change in a cross section corresponding to FIG. 2, and FIGS. 6 and 7 show the present production method as a change in a cross section corresponding to FIG. 3.

In the present production method, first, as shown in FIGS. 4A and 6A, the substrate S is prepared (preparation step).

Next, as shown in FIGS. 4B and 6B, the insulating layer 11 is formed on the substrate S (first insulating layer forming step). In this step, for example, a solution (varnish) of a resin for forming the insulating layer 11 is applied onto the substrate S and dried, thereby forming the insulating layer 11. When the insulating layer 11 has a predetermined pattern shape when viewed from the top, for example, a solution (varnish) of a photosensitive resin for forming the insulating layer 11 is applied onto the substrate S and dried, and thereafter, the coating thus formed is subjected to an exposure process through a predetermined mask, a subsequent development process, and if necessary, a subsequent bake process. In this way, the insulating layer 11 having a predetermined pattern is formed on the substrate S.

Next, as shown in FIGS. 4C and 6C, the wiring layer 21 is pattern-formed on the insulating layer 11 (first conductive portion forming step). Examples of a formation method of the wiring layer 21 include an additive method and a subtractive method. When the additive method is used in this step, for example, the wiring layer 21 is formed in the following manner.

First, a thin seed layer (not shown) which is a current-carrying layer for forming an electrolytic plating film is formed on the exposed surface of the insulating layer 11 by, for example, a sputtering method. Examples of a constituent material of the seed layer include copper, chromium, nickel, and alloys of these. Next, a resist pattern is formed on the seed layer. The resist pattern has an opening portion having a pattern shape corresponding to the pattern shape of the wiring layer 21. In the formation of the resist pattern, for example, a photosensitive resist film is attached onto the seed layer to form a resist film, and thereafter, the resist film is subjected to an exposure process through a predetermined mask, a subsequent development process, and if necessary, a subsequent bake process. In the formation of the wiring layer 21, next, a metal material is grown on the seed layer in a region within the opening portion of the resist pattern by an electrolytic plating method. As the metal material, preferably, copper is used. Next, the resist pattern is removed by etching. Next, a portion in the seed layer exposed by resist pattern removal is removed by etching. For example, as described above, it is possible to form the wiring layer 21 having a predetermined pattern on the insulating layer 11.

In the present production method, next, as shown in FIGS. 5A and 7A, the insulating layer 12 is formed on the insulating layer 11 so as to cover the wiring layers 21 and 21 (second insulating layer forming step). In this step, for example, a solution (varnish) of a photosensitive resin for forming the insulating layer 12 is applied onto the insulating layer 11 and the wiring layers 21 and 21 to be dried, and thereafter, a coating thus formed is subjected to an exposure process through a predetermined mask, a subsequent development process, and if necessary, a subsequent bake process. In this way, the insulating layer 12 having a predetermined pattern which covers the wiring layers 21 and 21 having a predetermined pattern is formed on the insulating layer 11. The insulating layer 12 is formed so as to have a recessed portion 12a (that is, thin enough to form the recessed portion 12a) at a position between the wiring layers 21 and 21 in the separation direction of the pair of wiring layers 21 and 21, as shown in FIG. 5A.

Next, as shown in FIGS. 5B and 7B, the wiring layer 22 is pattern-formed on the insulating layer 12 (second conductive portion forming step). Examples of a formation method of the wiring layer 22 include an additive method and a subtractive method. When the additive method is used in this step, the wiring layer 22 is, for example, formed in the following manner.

First, a thin seed layer (not shown) which is a current-carrying layer for forming an electrolytic plating film is formed on the exposed surface of the insulating layer 12 by, for example, a sputtering method. Examples of a constituent material of the seed layer include copper, chromium, nickel, and alloys of these. Next, a resist pattern is formed on the seed layer. The resist pattern has an opening portion having a pattern shape corresponding to the pattern shape of the wiring layer 22. In the formation of the resist pattern, for example, a photosensitive resist film is attached onto the seed layer to form a resist film, and thereafter, the resist film is subjected to an exposure process through a predetermined mask, a subsequent development process, and if necessary, a subsequent bake process. In the formation of the wiring layer 22, next, a metal material is grown on the seed layer in a region within the opening portion of the resist pattern by an electrolytic plating method. As the metal material, preferably, copper is used. Next, the resist pattern is removed by etching. Next, a portion in the seed layer exposed by resist pattern removal is removed by etching. For example, as described above, it is possible to form the wiring layer 22 having a predetermined pattern.

In the present production method, next, as shown in FIGS. 5C and 7C, the insulating layer 13 is formed on the insulating layer 12 so as to cover the wiring layer 22 (third insulating layer forming step). In this step, for example, a solution (varnish) of a photosensitive resin for forming the insulating layer 13 is applied onto the insulating layer 12 and the wiring layer 22 to be dried, and thereafter, a coating thus formed is subjected to an exposure process through a predetermined mask, a subsequent development process, and if necessary, a subsequent bake process. In this way, the insulating layer 13 having a predetermined pattern which covers the wiring layer 22 having a predetermined pattern is formed on the insulating layer 12.

For example, by undergoing the above-described steps, it is possible to produce the wiring circuit board X having the multilayer wiring structure portion.

The wiring circuit board X, as described above, includes the wirings which are routed in a multilayer wiring structure including the pair of wiring layers 21 and 21, and the wiring layer 22 extending along the wiring layers 21 while facing them. This wiring circuit board X is suitable for achieving the high density of the wiring.

Further, the wiring layer 22, as described above, has the ridge portion 22A protruding into the insulating layer 12 toward the region G between the wiring layers 21 and 21, and extending along the region G. Such a configuration is suitable for increasing the cross-sectional area (lateral cross-sectional area, for example, perpendicular to the extending direction of the wiring) of the wiring layer 22 by effectively utilizing a space between the wiring layers 21 and 21, and therefore, is suitable for achieving a decrease in electrical resistance such as DC resistance (low resistance).

As described above, the wiring circuit board X is suitable for achieving the high density, while achieving the low resistance of the wiring.

The ridge portion 22A of the wiring layer 22 works to ensure adhesion of the wiring layer 22 to the insulating layer 12 by an anchoring effect to the insulating layer 12, and therefore, is suitable for ensuring reliability of the wiring layer 22.

In the wiring circuit board X, the ridge portion 22A, as described above, has the apex portion 22a non-flat in a cross section (for example, a cross section shown in FIG. 2) in the width direction crossing the extending direction of the wiring layer 22. A configuration in which the ridge portion 22A has the apex portion 22a serves to ensure the adhesion of the wiring layer 22 to the insulating layer 12 by the anchoring effect of the ridge portion 22A to the insulating layer 12, and therefore, is suitable for ensuring the reliability of the wiring layer 22.

The ridge portion 22A, as described above, further has the curved side surface 22b disposed at one side of the apex portion 22a in the width direction and recessed inwardly in the wiring layer 22, and the curved side surface 22c disposed at the other side of the apex portion 22a in the width direction and recessed inwardly in the wiring layer 22. A configuration in which the ridge portion 22A has the curved side surfaces 22b and 22c in addition to the apex portion 22a serves to ensure the adhesion of the wiring layer 22 to the insulating layer 12 by the anchoring effect of the ridge portion 22A to the insulating layer 12, and therefore, is suitable for ensuring the reliability of the wiring layer 22.

The distance L1 between the pair of wiring layers 21 and 21, as described above, is preferably 5 μm or more, more preferably 8 μm or more, and preferably 30 μm or less, more preferably 20 μm or less. Such a configuration is suitable for achieving the high density of the wiring, while avoiding a short circuit between the wiring layers 21 and 21.

The distance L2 between the wiring layer 21 and the wiring layer 22 in the thickness direction, as described above, is preferably 2 μm or more, more preferably 5 μm or more, and preferably 20 μm or less, more preferably 15 μm or less. Such a configuration is suitable for achieving a thin wiring circuit board X, while avoiding a short circuit between the wiring layer 21 and the wiring layer 22.

In the wiring circuit board X, as shown in FIG. 8, a configuration in which the wiring layer 21 is electrically connected to the wiring layer 22 through a via 23 may be used. In this configuration, specifically, each of the pair of wiring layers 21 is electrically connected to the wiring layer 22 through the via 23 (for example, the plurality of vias 23 between each wiring layer 21 and the wiring layer 22) penetrating the insulating layer 12.

### INDUSTRIAL APPLICATION

The wiring circuit board of the present invention may be applied to various flexible wiring circuit boards and rigid wiring circuit boards.

### DESCRIPTION OF REFERENCE NUMERALS

X Wiring circuit board

R1 Component mounting region

R2 Wiring formation region

S Substrate

11 Insulating layer (first insulating layer)

12 Insulating layer (second insulating layer)

13 Insulating layer (third insulating layer)

21 Wiring layer (first wiring layer)

22 Wiring layer (second wiring layer)

22A Ridge portion

22a Apex portion

22b Curved side surface (first curved side surface)

22c Curved side surface (second curved side surface)

23 Via

Region (region between first wiring layers)

1. A wiring circuit board comprising:
a first insulating layer,
a pair of first wiring layers disposed on the first insulating layer and extending side by side apart from each other,
a second insulating layer disposed on the first insulating layer so as to cover the pair of first wiring layers, and
a second wiring layer disposed on the second insulating layer and extending along the pair of first wiring layers, the second wiring layer facing to the pair of first wiring layers in a thickness direction of the first wiring layer,
wherein the second wiring layer has a ridge portion protruding into the second insulating layer toward a region between the pair of first wiring layers, and extending along the region.

2. The wiring circuit board according to claim 1,
wherein the ridge portion has an apex portion non-flat in a cross section in a width direction crossing an extending direction of the second wiring layer.

3. The wiring circuit board according to claim 2,
wherein the ridge portion further has a first curved side surface disposed at one side of the apex portion in the width direction and recessed inwardly in the second wiring layer, and a second curved side surface disposed at the other side of the apex portion in the width direction and recessed inwardly in the second wiring layer.

4. The wiring circuit board according to claim 1,
wherein a distance between the first wiring layer and the second wiring layer in the thickness direction is 2 μm or more and 20 μm or less.

5. The wiring circuit board according to claim 1,
wherein a distance between the pair of first wiring layers is 5 μm or more and 30 μm or less.
